(19) United States
(12) Patent Application Publication
(10) Pub. No.: US 2011/0259416 A1
(43) Pub. Date: Oct. 27, 2011

(54) ENVIRONMENTAL BARRIER PROTECTION FOR DEVICES

(76) Inventors: Rebekah K. Feist, Midland, MI (US); Mark T. Bernius, Midland, MI (US); Christopher P. Christenson, Midland, MI (US)

(21) Appl. No.: 13/094,034

(22) Filed: Apr. 26, 2011

Related U.S. Application Data
(60) Provisional application No. 61/328,237, filed on Apr. 27, 2010.

(51) Int. Cl. H01L 31/0216

(52) U.S. Cl. 136/256

(57) ABSTRACT

Embodiments of the invention provide an article comprising a photovoltaic device structure and a barrier layer comprising mica on the photovoltaic device structure. The barrier layer is flexible and light transmissive.

### CROSS-REFERENCE STATEMENT

This application claims benefit under 35 U.S.C. §119(e) of U.S. Provisional Application Number 61/328,237 filed Apr. 27, 2010 and the entire content of the application is hereby incorporated herein by reference.

### FIELD OF INVENTION

The invention relates to environmental barrier protection for environmentally sensitive photovoltaic devices and also methods of providing the barrier protection for photovoltaic devices.

### BACKGROUND

Certain photovoltaic devices, particularly thin-film chalcogenide based devices, are sensitive to environmental reactive species such as oxygen and water vapor, the permeation of which causes deterioration of these devices. Typically barrier coatings are provided over the devices to protect them from oxygen and water vapor permeation.

Multilayered barrier coatings made of alternating layers of materials of various organic and inorganic compositions are known. Such layers commonly have different indices of refraction, normally resulting in degradation of light transmission through the barrier coating. Desired optical performance can be achieved by optimizing the thickness of the organic composition layer typically by maintaining it as thin as possible; however this may degrade the barrier properties of the coating. Moreover, mass production of these barrier layers can be a challenge as it may require controlling the thickness of each layer as well as addressing adhesion of the layers. In addition, multi-layered barrier coatings that meet all the requirements for long product lifetime have not been achieved to applicants' knowledge.

Glass is another alternative that offers excellent barrier protection and light transmission for devices. However, for devices requiring flexibility incorporation of glass can be a limitation due to its lack of flexibility. The relative rigidity of the glass barrier negates a major benefit of the flexible thin-film photovoltaic cells.

It would therefore be desirable to provide barrier coatings for devices that are robust and have desirable optical properties.

### SUMMARY OF THE INVENTION

Embodiments of the present invention provide improved barrier layers for environmentally sensitive photovoltaic devices. Accordingly, in one embodiment of the present invention an article is provided. The article includes a photovoltaic device structure and a barrier layer comprising mica disposed over the photovoltaic device structure. The barrier layer is flexible and light transmissive.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic diagram of an article according to embodiments of the present invention;

FIG. 2 is a schematic diagram of another article in accordance with embodiments of the present invention;

FIG. 3 is a plot of normalized efficiency against exposure time, displaying the performance of photovoltaic device structures exposed to a test environment according to some embodiments of the present invention.

### DETAILED DESCRIPTION

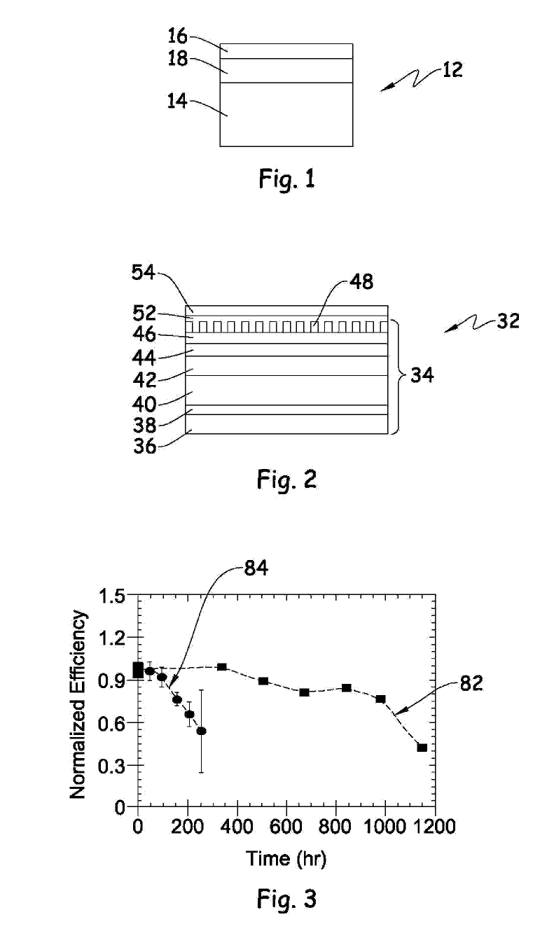

FIG. 1 is a schematic diagram of an article according to embodiments of the present invention. The article includes a photovoltaic (PV) device structure 12 having a photovoltaic cell 14.

In preferred embodiments, the photovoltaic device structure 12 is flexible. In one embodiment, the photovoltaic device structure 12 is sufficiently flexible to be wrapped around a mandrel having a diameter of 50 cm, preferably about 40 cm, more preferably about 25 cm without cracking at a temperature of 25° C. The flexibility of the photovoltaic device structure 12 may allow it to be mounted to surfaces incorporating some curvature.

In one embodiment, the PV device structure 12 includes at least one thin-film PV cell 14. In certain embodiments, the PV device structure 12 includes an array of thin-film PV cells 14. The maximum benefit of this invention is achieved when mica is used as a barrier for a flexible and/or environmentally sensitive photovoltaic device. Thus, the PV cell 14 preferably is a thin-film photovoltaic cell, a dye-sensitized photovoltaic cell, an organic/polymer photovoltaic cell and/or an inorganic photovoltaic cell. In one particularly preferred embodiment, the photovoltaic cell 14 is a chalcogenide-based thin-film photovoltaic cell. While pv cell 14 is shown as a single element it may and typically will include various components (e.g. multiple layers, electrical contacts, etc.)

Barrier protection is typically provided on a top surface of the PV device structure 12 and/or of the PV cell 14 that is exposed to the external environment. A barrier layer 16 is disposed on the PV cell 14. However, in certain embodiments a barrier can be provided around the entire PV cell 14. For example, the PV cell 14, or the PV device structure 12 or both can be encapsulated within a barrier that includes a top barrier layer 16.

In this invention the topside barrier layer 16 comprises mica. Mica is a class of naturally occurring minerals which are typically a complex hydrous aluminum silicate. Synthetic micas are also known. In one embodiment, the mica is selected from a group consisting of muscovite, phlogopite, biotite, lepidolite, roscoelite, fuchsite, fluorophlogopite, paragonite, anandite, celadonite, clintonite, ephesite, glauconite, hendricksite, illite, margarite, polylithionite, taenolite and zinnwaldite. In another embodiment, the mica is muscovite mica.

Mica is known primarily for its electrical and heat resistant properties. It is conventionally employed in the electronics industry as an electrical insulator (dielectric), for example, in capacitors. While U.S. Pat. No. 5,355,089 disclosed the application of a moisture barrier film comprising mica over a cell tester applied along a battery's outer surface, the specific materials and conditions of use are significantly different from those found in a photovoltaic cell. Specifically, the cell tester is an electrochemical cell attached along a wall of the battery. The cell tester includes an anode composed of a thin layer of zinc deposited on a polyester film; a cathode composed of a thin layer of manganese dioxide and an aprotic organic electrolyte disposed between the cathode and the anode. In contrast, the photovoltaic cell is a solid state device composed of a semiconducting material such as a chalgogenide-based material. In addition, unlike the cell tester which is likely exposed to interior ambient conditions, photovoltaic cells are intended and designed to be often located outdoors and are exposed to harsher environmental conditions such as hail; snow etc. A material that shows excellent barrier properties at ambient indoor environment may fail at much harsher, outdoor environment. Surprisingly, applicants have discovered that mica provides an excellent barrier for environmentally sensitive photovoltaic devices. Another distinction and challenge in manufacture of photovoltaic devices is the larger surface area protection as opposed to smaller area typically found in an electrochemical cell tester. Preferably, the area of the light exposed portion of the photovoltaic cell is at least about one square inch (6.4 square centimeters), and more preferably at least about 4 square inches (25 square centimeters). In one embodiment, the area of the light exposed portion of the photovoltaic cell is at least about two hundred square inches (about 1290 square centimeters).

In some embodiments, the barrier layer 16 consists essentially of mica. In one embodiment, the barrier layer 16 can be a sheet of mica. In certain embodiments, the barrier layer 16 can be multiple sheets of mica. In certain other embodiments, the barrier layer 16 can be a multilayered structure having at least one layer consisting of mica. The barrier layer 16 having the multilayered structure can further include inorganic layers, organic layers or a combination of these.

In some embodiments, the barrier layer 16 has a size of at least about at least about one square inch (6.4 square centimeters), and more preferably at least about 4 square inches (25 square centimeters) and yet more preferably at least 100 square centimeters, and most preferably at least 500 square centimeters. In one embodiment, barrier layer has an area of least about two hundred square inches (about 1290 square centimeters).

In some embodiments, the barrier layer 16 can have a thickness of greater than about 0.4 mils (10.0 μm (micrometers)). In certain embodiments, the barrier layer 16 can have a thickness in the range of about 1 mils (25.4 μm) to about 4 mils (101.6 μm). In some embodiments, the barrier layer 16 can have a thickness of about 8 mils (203.2 μm), or greater than about 8 mils. As will be appreciated, increasing a thickness of the barrier layer 16 may improve the barrier property of the layer 16, however, this may compromise a flexibility of the barrier layer 16. Accordingly, the thickness of the barrier layer 16 can be decided based on the intended application of the article 10.

The barrier layer 16 is flexible and light transmissive. In one embodiment, the barrier layer 16 comprising a mica sheet having a thickness of 100 micrometers can be bent around a roller having a diameter of 1 inch (2.54 centimeters) a number of times without any visible signs of wear, crack or stress to the barrier layer 16. The barrier layer 16 is sufficiently light transmissive in the near infrared and visible range as measured by the transmittance at these wavelengths. In some embodiments, the barrier layer 16 has a transmittance of light of at least about 80% for wavelengths between 340 nm and 3000 nm. In one embodiment, the barrier layer 16 comprising a mica sheet of 100 micrometers thickness (NSC Mica Exports Private Ltd.) has a transmittance of light of at least about 100% between 340 nm and 3000 nm.

In some embodiments, the barrier layer 16 has a water vapor transmission rate (WVTR) of no more than about 10⁻³ g/m²·day, preferably no more than about 10⁻⁴ g/m²·day, more preferably no more than about 10⁻⁵ g/m²·day, and most preferably no more than about 10⁻⁶ g/m²·day. The WVTR for a material may be determined according to the methodology described in ASTM F-1249 or in other tests such as the calcium test (Wolf et al. Plasma Processes and Polymers, 2007, 4, S185-S189). In some embodiments, the barrier layer 16 has an oxygen transmission rate (OTR) of no greater than about 10⁻⁴ g/m²·day and preferably no greater than about 10⁻⁵ g/m²·day. The OTR for a material may be determined according to the methodology described in ASTM D-3985.

An adhesion layer 18 is preferably disposed between the PV device structure 12 and the barrier layer 16. The adhesion layer 18 may advantageously improve adhesion between the PV device structure 12 and the barrier layer 16. Example materials for adhesion layer 18 include hot melt adhesives such as ethylene vinyl acetate (EVA). However, such adhesion layer is optional.

As will be appreciated, the article 10 can further include additional layers to improve an efficiency of the PV device structure 12. The additional layers can be between the PV device structure 12 and the barrier layer 16 and/or over the barrier layer 16. Exemplary additional layers include anti-reflective coatings, smoothing layers and additional barrier coatings.

FIG. 2 is an article according to another embodiment of the invention. The article includes a PV device structure 32. The PV device structure 32 is similar to the PV device structure 12, as described previously with reference to FIG. 1.

A typical PV cell 34 within the PV device structure 32 is illustrated in FIG. 2. The PV cell 34 includes an optional substrate 36, a back electrical contact 38, an absorber layer 40, a buffer layer 42, an optional window layer 44, a transparent conductive layer 46 and a conductive grid structure 48.

The optional substrate 36, in one embodiment, is flexible. Suitable materials for the substrate 36 include glasses, polymers, ceramic materials and metals. In embodiments where the PV device structure 32 includes more than one PV cell 34, the substrate 36 can be a continuous structure, in a direction parallel to the longest surface of the substrate 36, upon which each of the layers of the PV cells 34 can be deposited. In some embodiments, the substrate 36 can be a discrete structure restricted to one particular PV cell 34. Advantageously, the substrate 36 can provide mechanical strength to the photovoltaic device structure 32 and/or the PV cell 34. In embodiments where the substrate 36 is made of a conductive material, such as a molybdenum foil, the substrate 36 can provide mechanical strength and can also perform as an electrical contact thereby eliminating the need for the back electrical contact 38.

Referring to FIG. 2, a back electrical contact 38 is deposited optionally on a front surface of the optional substrate 36. The back electrical contact 38 provides a convenient way to electrically couple PV cell 34 to external circuitry. The back electrical contact 38 may be formed from a wide range of electrically conductive materials, including one or more of Cu, Mo, Ag, Al, Cr, Ni, Ti, Ta, Nb, W or any combinations of these, and the like.

The absorber layer 40 is deposited on the back electrical contact 38. In embodiments where the back electrical contact 38 is deposited on the back surface of the substrate 34, the absorber layer 40 can be provided on the front surface of the substrate 34. The absorber layer 40 can be a single integral layer as illustrated or can be formed from one or more layers. As will be appreciated, the absorber layer 40 absorbs light energy and then photovoltaically converts the light energy into electric energy. Suitable material for the absorber layer 40 includes a copper containing chalcogenide. In one embodiment, the absorber layer 40 is a doped or undoped IB-IIIB-chalcogenide, such as IB-IIIB-selenides, IB-IIIB-sulfides, and IB-IIIB-selenides-sulfides that includes copper and at least one of indium, aluminum or gallium. Example chalcogenides include copper indium selenides (CuInSe), copper indium gallium selenides (CuInGaSe also referred to as CIGS), copper gallium selenides (CuGaSe), copper indium sulfides (CuInS), copper indium gallium sulfides (CuInGaS), copper indium sulfide selenides (CuInSSe), copper gallium sulfide selenides (CuGaSSe), copper indium aluminum selenides (CuInAlSe), copper indium aluminum gallium sulfide (CuInAlGaS), copper indium aluminum sulfide (CuInAlS) and copper indium gallium sulfide selenides (CuInGaSSe).

The absorber layer 40 may be formed by any suitable method using a variety of one or more techniques such as evaporation, sputtering, electrodeposition, spraying, and sintering. In one embodiment, the absorber layer 40 is formed by co-evaporation of the constituent elements from one or more suitable sources, where the individual constituent elements are thermally evaporated on a hot surface coincidentally at the same time, sequentially, or a combination of these to form layer 40. After deposition, the deposited materials may be subjected to one or more further treatments to finalize the layer 40. In many embodiments, the absorber layer 40 has p-type characteristics.

The chalcogenide absorber layer 40 may be doped with other materials such as sodium (Na), lithium (Li), one of the lanthanoid series of elements (Ln) or a combination thereof as is known in the art. The lanthanoid series of elements (previously lanthanide) series comprises the fifteen elements with atomic numbers 57 through 71, from lanthanum (La) to lutetium (Lu). Preferred members of the lanthanoid series of elements for inclusion in the absorber layer 40 include La or Europium (Eu). Beneficial effects of the inclusion of Na, Li or the lanthanoid series of elements include increases in p-type conductivity, texture, and average grain size. Doping of the chalcogenide-containing absorber layer 40 can be achieved in several ways including diffusion of such metal ions from the substrate 36 or an adjacent layer deposited prior to the absorber layer 40 formation or diffusion from a solution containing the dopant following absorber layer 40 formation. In one embodiment, sodium doping of the chalcogenide-containing absorber layer 40 can be achieved via diffusion from a soda-lime glass substrate or from a layer of sodium fluoride deposited between the back electrical contact 38 (Mo) and the chalcogenide-containing absorber layer 40.

Advantageously, the chalcogenide-containing absorber layer 40 exhibit excellent cross-sections for light absorption, when compared to silicon based PV cell, which allows layer 40 to be very thin and flexible. In preferred embodiments, the absorber layer 40 can have a thickness in the range from about 1 micrometer to about 5 micrometers, preferably about 2 micrometers to about 3 micrometers.

According to some embodiments, the buffer layer 42 is formed on the absorber layer 40. In one embodiment, the buffer layer 42 comprises a sulfide or an oxide of a metal selected from a group consisting of cadmium, zinc, indium and any combinations thereof. The buffer layer 42 can be a single integral layer as illustrated or can be formed from one or more layers. For example, in a multi-layered buffer layer, a lower layer of the buffer layer can be formed from a layer comprising cadmium and sulfur and an upper layer from a layer comprising zinc and sulfur. These buffer layers are believed to be particularly sensitive to exposure to moisture.

As shown, the PV cell 34 includes an optional window layer 44 having a single integral layer. In certain embodiments, the window layer 44 can be formed from one or more layers. The window layer 44 can help to protect against shunts. The window layer 44 also may protect buffer layer 42 during subsequent deposition of the transparent conducting layer 46. The window layer 44 may be formed from a wide range of materials and often is formed from a resistive, transparent oxide such as an oxide of Zn, In, Cd, Sn, combinations of these and the like. An exemplary window layer material is ZnO. A typical window layer 44 may have a thickness in the range from about 10 nm to about 200 nm, preferably about 50 nm to about 150 nm, more preferably about 80 nm to about 120 nm.

The transparent conducting layer 46 is interposed between the optional window layer 44 and the conductive grid structure 48. In embodiments, where the window layer 44 is not present, the transparent conducting layer 46 can be in direct contact with the buffer layer 42. One or more intervening layers optionally may be interposed for a variety of reasons such as to promote adhesion, enhance electrical performance, or the like. In many suitable embodiments where the transparent conducting layer 46 is a transparent conductive oxide (TCO), the TCO layer has a thickness in the range from about 10 nm to about 1500 nm, preferably about 150 nm to about 200 nm A wide variety of TCO or combinations of these may be incorporated into the transparent conducting layer 46. Examples include fluorine-doped tin oxide, cadmium-doped tin oxide, tin oxide, indium oxide, indium tin oxide (ITO), aluminum doped zinc oxide (AZO), gallium doped zinc oxide, zinc oxide, combinations of these, and the like. In one illustrative embodiment, the transparent conducting layer 46 is indium tin oxide. TCO layers are conveniently formed via sputtering or other suitable deposition techniques.

The transparent conducting layer 46 may alternatively be a very thin metal film (e.g., a metal film having a thickness greater than about 5 nm, and more preferably greater than about 30 nm). As used herein, the term “metal” refers not only to metals, but also to metal admixtures such as alloys, intermetallic compositions, combinations of these, and the like. These metal compositions optionally may be doped. Examples of metals that could be used to form transparent conducting layer 46 include the metals suitable for use in the back electrical contact 38, combinations of these, and the like. The transparent conducting layer 46 is preferably less than about 200 nm thick, more preferably less than about 100 nm thick. These representative embodiments result in films that are sufficiently transparent to allow incident light to reach the absorber layer 40.

The PV cell 34 includes the conductive grid structure 48 comprising one or more electrical contacts in electrical contact with the transparent conducting layer 46. The grid structure 48 may be deposited over the transparent conducting layer 46 to reduce the sheet resistance of this layer. Electrical contacts can be formed from a wide range of electrically conducting materials, but most desirably are formed from one or more metals, metal alloys, or intermetallic compositions. Exemplary electrically conducting materials include one or more of Ag, Al, Cu, Cr, Ni, Ti, combinations of these, and the like. Electrical contacts incorporating Ag are preferred. To improve the adhesion quality of the interface between the electrical contacts and the transparent conducting layer 46, an optional adhesion promoting film (not shown) may be used. In a typical embodiment, the adhesion promoting film has a thickness in the range from about 10 nm to about 500 nm, preferably about 25 nm to about 250 nm, more preferably about 50 nm to about 100 nm. The adhesion promoting film can be formed from a wide range of materials. Preferred embodiments of the adhesion promoting film incorporate electrically conductive metal constituents such as Ni. The adhesion promoting film is formed prior to deposition of electrical contacts on transparent conducting layer 46.

Referring to FIG. 2, an optional adhesion layer 52 is provided over the conductive grid structure 48 and the transparent conducting layer 46. In one embodiment, the adhesion layer 52 can be provided on the conductive grid structure 48, and covering a top surface of the conductive grid structure 48 and a portion of the transparent conducting layer 46. In certain other embodiments, the adhesion layer 52 can be provided along the side edges of the substrate 36 and across side surfaces of the overlying layers thus encasing the underlying layers. The adhesion layer 52 is similar to the adhesion layer 20, as described previously with reference to FIG. 1.

It has been observed that when chalcogenide-based PV cells are used, certain materials that form the top layer of PV cell, such as AZO or cadmium sulfide are prone to degradation in moisture-rich and/or oxygen-rich environments. This environmental sensitivity puts an added burden on the choice of encapsulation or packaging scheme for the PV cell, in that a transparent and completely air- and water-tight front side to the cell must be provided with the traditional configuration of the chalcogenide-based PV cells. Glass has been identified as one of the material which meets the necessary barrier properties to protect such sensitive materials. Unfortunately, if glass is used, the cell may not have the desirable flexibility. Accordingly, embodiments of the present invention provide a barrier layer 54 comprising mica that is flexible as well as light transmissive.

The barrier layer 54 is the same as the barrier layer 18, described previously with reference to FIG. 1. In some embodiments, the PV device structure 32 and/or the PV cell 34 can be encapsulated by the barrier layer 54. In one embodiment, providing the barrier layer 54 includes providing a sheet of mica.

As will be appreciated, the article 30 can further include additional layers to improve an efficiency of the PV device structure 32 and/or the PV cell 34. The additional layers can be between the layers of the PV cell 34, and/or between the PV device structure 32 and the barrier layer 54, and/or over the barrier layer 54. Exemplary additional layers include anti-reflective coatings, smoothing layers and additional barrier coatings.

Without further elaboration, it is believed that one skilled in the art can, using the description herein, utilize the present invention to its fullest extent. The example provided is merely representative of the work that contributes to the teaching of the present application. Accordingly, this example is not intended to limit the invention, as defined in the appended claims, in any manner

### EXAMPLE 1

This Example illustrates the barrier property of mica provided over a PV cell and/or a PV device structure.

A laminated PV device structure is constructed. A 0.7 mm thick borosilicate glass (BSG) substrate is taken and a thin sheet (100 micrometers) of first adhesion layer consisting of ethylene vinyl acetate (EVA) is provided on the substrate. A flexible copper indium gallium selenide type (CIGS) thin-film PV cell having a light exposed area of about 8.1 square centimeters with wire ribbons attached to the top silver (Ag) collection grid and to a bottom stainless steel substrate, is placed over the first adhesion layer. A second adhesion layer of EVA is provided over the PV cell. A mica sheet that is 2″×2″square inches (10.16 square centimeters) in size and 10 microns in thickness is provided on the second adhesion layer to form a PV device structure. The PV device structure is then sealed to form the laminated PV device structure forming adhesion region around the PV cell. A hot compression laminator operating at temperatures of 120 degree Celsius for a time period of 12 minutes is used for sealing the PV device structure.

The laminated PV device structure is then clamped over a bottom metal package. A silicone O-ring seal is clamped by means of a top metal package to minimize moisture ingress through edges and sides of the laminated PV device structure. The laminated PV device structure is then exposed to a test environment, where it is subjected to a temperature of 85 degree Celsius in a 100% humid environment, for an exposure time extending up to 950 hours and consisting of several exposure time steps. The laminated PV device structure is then removed from the test environment and placed in a dry nitrogen purge box for about 24 hours. The performance or the efficiency of the laminated PV device structure is obtained from light biased J-V curves collected using a SpectraNova Class AAA solar simulator, meeting IEC60904-9 standards, operating at 1000 Watts per square meters. The solar simulator light intensity was calibrated using a silicon reference cell with BK-7 filter. The same process is followed for measuring the performance of the laminated PV device structure for each exposure time steps. FIG. 3 is a plot of normalized efficiency of the device against time of exposure to the test environment, where 82 is a performance curve corresponding to PV device with mica laminated to a CIGS PV device structure.

Similarly, a laminated PV device structure without the mica sheet is constructed using the above procedure. A performance curve 84 corresponding to the performance of PV device without the mica sheet is provided on plot. The normalized efficiency of the PV device without mica falls to about 50 percent in about 250 hours while the PV device with mica it takes more than about 1000 hours. The plot clearly shows the superior barrier property of mica.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An article comprising:
a photovoltaic device structure; and
a barrier layer comprising mica disposed over the photovoltaic device structure, wherein the barrier layer is flexible and light transmissive.

2. The article of claim 1 further comprising an adhesion layer between the photovoltaic device structure and the barrier layer.

3. The article of claim 1, wherein the photovoltaic device structure is flexible.

4. The article of claim 1, wherein the photovoltaic device structure comprises at least one thin-film photovoltaic cell.

5. The article of claim 1, wherein the photovoltaic device structure comprises a chalcogenide based thin-film photovoltaic cell.

6. The article of claim 5, wherein the thin-film photovoltaic cell comprises a back electrical contact, an absorber layer, a buffer layer and a transparent conductive layer.

7. The article of claim 6, wherein the absorber layer comprises a copper containing chalcogenide.

8. The article of claim 7, wherein the buffer layer comprises a sulfide or an oxide of a metal selected from a group consisting of cadmium, zinc, indium and any combinations thereof.

9. The article of claim 1, wherein the barrier layer has a water vapor transmission rate of at least about 10⁻³ grams per square meter per day.

10. The article of claim 9, wherein the barrier layer has a water vapor transmission rate of at least about 10⁻⁵ grams per square meter per day.

11. The article of claim 1, wherein the barrier layer has an oxygen transmission rate of at least about 10⁻⁴ grams per square meter per day.

12. The article of claim 1, wherein the barrier layer has a transmittance of light of at least about 80% for wavelengths between 340 nm and 3000 nm.

13. The article of claim 1, wherein the barrier layer consists essentially of mica.

14. The article of claim 1, wherein the barrier layer has a thickness of greater than about 0.8 mils.

15. The article of claim 1, wherein the barrier layer comprises an area of greater than 1 square inch.
